(19) United States
(12) Patent Application Publication
(10) Pub. No.: US 2024/0332313 A1
(43) Pub. Date: Oct. 3, 2024

(54) LIGHT EMITTING DISPLAY DEVICE AND METHOD OF MANUFACTURING THEREOF

(71) Applicant: Samsung Display Co., LTD., Yongin-si (KR)

(72) Inventors: Kyung-Bae KIM, Yongin-si (KR); Do Yeong PARK, Yongin-si (KR); Ki Hyun PYO, Yongin-si (KR); Sung Chul HONG, Yongin-si (KR)

(21) Appl. No.: 18/412,142

(22) Filed: Jan. 12, 2024

(30) Foreign Application Priority Data
Mar. 30, 2023 (KR) 10-2023-0042072

(51) Int. Cl. H01L 27/12; H01L 25/075; H01L 33/62

(52) U.S. Cl. CPC H01L 27/124; H01L 25/0753; H01L 33/62

(57) ABSTRACT

A light emitting display device, includes: a substrate; a driving element layer on the substrate and including a transistor and a planarization layer covering the transistor; a cathode and an anode connection electrode on the planarization layer; a separator on the planarization layer and including a first layer and a second layer, wherein the second layer protrudes from the first layer of the separator; a pixel defining layer including a first pixel defining layer on the separator and a second pixel defining layer superimposed with a portion of the cathode and a portion of the anode connection electrode; a light emitting layer on top of the cathode; and an anode connecting electrode, the second pixel defining layer, and an anode above the light emitting layer.

### CROSS-REFERENCE TO RELATED APPLICATION

The present application claims priority to and the benefit of Korean Patent Application No. 10-2023-0042072 filed on Mar. 30, 2023, in the Korean Intellectual Property Office, the entire disclosure of which is incorporated herein by reference.

### BACKGROUND

### 1. Field

Aspects of some embodiments of the present disclosure relate to a light emitting display device and a manufacturing method thereof.

### 2. Description of the Related Art

A display device is a device having a screen or display panel for displaying images, and includes a liquid crystal display (LCD), an organic light emitting diode (OLED), and the like.

Display devices may be utilized in a variety of electronic devices, such as mobile phones, navigation, digital cameras, electronic books, portable game consoles, or various terminals.

Organic light emitting display devices generally have self-luminance characteristics and, unlike liquid crystal displays, generally do not require a separate light source, so thickness and weight can be reduced.

In addition, organic light emitting display devices generally have relatively high-grade characteristics such as relatively low power consumption, relatively high luminance, and relatively fast response speed.

The above information disclosed in this Background section is only for enhancement of understanding of the background and therefore the information discussed in this Background section does not necessarily constitute prior art.

### SUMMARY

The light emitting display device according to some embodiments includes a substrate, a driving element layer positioned on the substrate and including a transistor and a planarization layer covering the transistor, a cathode and an anode connection electrode positioned on the planarization layer, a separator positioned on the planarization layer and a first layer and a second layer, wherein the second layer is protruding from the first layer of the separator, a pixel defining layer including a first pixel defining layer positioned on the separator and a second pixel defining layer superimposed with a portion of the cathode and a portion of the anode connection electrode, a light emitting layer positioned on top of the cathode; And an anode connection electrode, the second pixel defining layer, and an anode positioned on the light emitting layer.

According to some embodiments, the first layer of the separator may be formed narrower in width than the second layer.

According to some embodiments, the first pixel defining layer may have a width narrower than the width of the second layer and the first layer of the separator overlapping the first pixel defining layer.

According to some embodiments, the light emitting layer may be positioned in a first opening divided by the separator overlapping the second pixel defining layer and the first pixel defining layer.

According to some embodiments, the anode may be connected to the anode connection electrode through a second opening divided by the separator overlapping the second pixel defining layer and the first pixel defining layer.

According to some embodiments, the second pixel defining layer may be positioned between the first opening and the second opening.

According to some embodiments, positioned on the first pixel defining layer and the separator overlapping therewith, it may further include an auxiliary electrode formed of the same material as the anode.

According to some embodiments, a first functional layer may be positioned between the light emitting layer and the anode, and including a hole transport layer; and a second functional layer including an electron delivery layer positioned between the light emitting layer and the cathode.

According to some embodiments, the second layer of the separator is an inorganic insulating layer, and the first layer may be an organic insulating layer.

According to some embodiments, the second layer of the separator is an inorganic insulating layer, and the first layer may be an inorganic insulating layer having an etching rate different from the second layer.

A method for manufacturing an light emitting display device according to some embodiments includes forming a transistor on a substrate, a planarization layer covering the transistor, a cathode and an anode connection electrode positioned on the planarization layer, forming a primary structure of the separator by sequentially stacking a material for a first layer and a material for a second layer constituting a separator, and first etching; forming a first pixel defining layer on the primary structure of the separator, forming a photoresist pattern covering the first pixel defining layer and exposing the side of the primary structure of the separator and etching the primary structure of the separator exposed through dry etching to complete a second layer of the separator protruding from the first layer of the separator.

According to some embodiments, the second layer and the first layer included in the primary structure of the separator may be formed of the same width as each other.

According to some embodiments, in the step of forming a first pixel defining layer on the primary structure of the separator, the first pixel defining layer positioned above the primary structure of the separator is a second layer included in the primary structure and the first layer narrower than the width may be formed.

According to some embodiments, the step of forming a first pixel defining layer on the primary structure of the separator may also form a second pixel defining layer that does not overlap with the separator.

According to some embodiments, the second pixel defining layer may overlap with a portion of the cathode and a portion of the anode connection electrode.

According to some embodiments, the method may further include forming an inkjet light emitting layer in a first opening divided by the separator overlapping the second pixel defining layer and the first pixel defining layer.

According to some embodiments, the light emitting layer may include a quantum dot.

According to some embodiments, the step of completing the second layer of the protruding separator may be performed through anisotropic dry etching.

According to some embodiments, the material for the second layer is an inorganic insulating material, and the material for the first layer may be an organic insulating material.

According to some embodiments, the material for the second layer is an inorganic insulating material, and the material for the first layer may be an inorganic insulating material having an etching rate different from the material for the second layer.

According to some embodiments, a pixel defining layer is formed on top of the separator so that the hydrophobic characteristics of the surface of the pixel defining layer are not deteriorated, and a light emitting layer can be formed between the pixel defining layer in an inkjet manner.

On the other hand, according to some embodiments, a pixel defining layer can be formed on the separator to reduce the area occupied to reduce the gap between the light emitting device and form a high-resolution light emitting display device.

### BRIEF DESCRIPTION OF THE DRAWINGS

FIG. 1 is a circuit diagram of a pixel of a light emitting display device according to some embodiments.

FIG. 2 is a cross-sectional view of a light emitting display device according to some embodiments.

FIG. 3 is a schematic cross-sectional view illustrating the manufacturing order of a portion of a light emitting display device according to some embodiments.

FIG. 4 to FIG. 10 are cross-sectional views shown according to the manufacturing order of the embodiments of FIG. 2.

FIG. 11 is a drawing illustrating the cross-sectional structure of the light emitting layer between the comparative example and some embodiments of the present disclosure.

FIG. 12 is a cross-sectional view illustrating one step of a method of manufacturing a light emitting display device according to some embodiments.

FIG. 13 is a cross-sectional view of a portion of a light emitting display device according to some embodiments.

FIG. 14 is a schematic drawing illustrating a cross-sectional structure of a plurality of comparative examples.

### DETAILED DESCRIPTION

Hereinafter, with reference to the accompanying drawings, aspects of various embodiments will be described in more detail so that those skilled in the art can implement them.

The present invention may be implemented in various different forms and is not limited to the embodiments described herein.

In order to more clearly describe aspects of some embodiments of the present invention, description of some portions that may be irrelevant or unnecessary to enable a person having ordinary skill in the art to make and use embodiments according to the present disclosure may be omitted, and the same reference numerals and symbols will be attached to the same or similar constituent elements throughout the specification.

In addition, because the size and thickness of each configuration shown in the drawings may be arbitrarily shown for convenience of description, embodiments according to the present invention are not necessarily limited to those shown.

In the drawings, the thickness of layers, films, panels, regions, etc., are exaggerated for clarity.

In the drawing, the thickness is enlarged to clearly represent various layers and regions.

In addition, when a part of a layer, membrane, region, plate, constituent element, etc. is “above” or “on” another part, it includes not only the case “directly on” the other part, but also the case where there is another part in between.

In contrast, when an element is referred to as being “directly on” another element, there are no intervening elements present.

In addition, being “above” or “on” the reference portion is positioned above or below the reference part, and does not necessarily mean that it is positioned “above” or “on” the opposite direction gravity. In addition, unless explicitly described to the contrary, the word “include”, and variations such as “includes” or “including”, will be understood to imply the inclusion of stated elements but not the exclusion of any other elements.

In addition, in the entire specification, when we say “plan”, this means when the target part is viewed from above, and when we say “cross-section”, we mean when the cross-section cut vertically of the target part is viewed from the side.

In addition, throughout the specification, when “connected”, it does not mean only when two or more constituent elements are directly connected, but also when two or more components are indirectly connected through another constituent component, when physically connected or electrically connected, as well as when each part that is substantially integrated but referred to by different names according to position or function is connected to each other.

In addition, in the entire specification, when a portion of a wiring, layer, membrane, region, plate, constituent element, etc. is “extended in the first direction or second direction”, it does not mean only a straight line shape straight in that direction, but also a structure that extends generally along the first or second direction, and is bent in one part, has a zigzag structure, or extends while including a curved line structure.

In addition, electronic devices (e.g., mobile phones, TVs, monitors, notebook computers, etc.) including display devices, display panels, and the like described in the specification, or electronic devices including display devices, display panels, etc. manufactured by the manufacturing method described in the specification are also not excluded from the scope of rights herein.

Hereinafter, the following description, in conjunction with the figures, illustrates and describes further details of a light emitting display device according to the present disclosure.

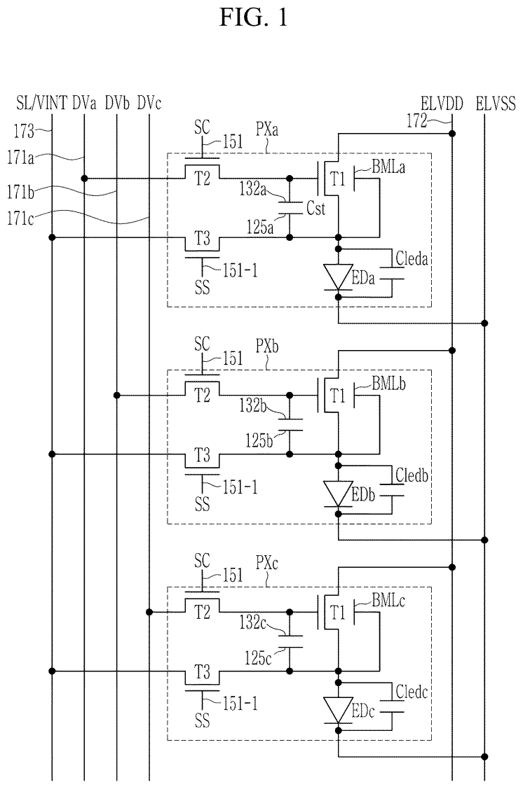

FIG. 1 is a circuit diagram of a pixel of a light emitting display device according to some embodiments.

FIG. 1 shows a circuit diagram of three pixels (PXa, PXb, PXc) including a group of light emitting diodes (LED) (EDa, EDb, EDc).

The plurality of pixels may include a first pixel (PXa), a second pixel (PXb), and a third pixel (PXc).

Each of the first pixel (Pxa), the second pixel (PXb), and the third pixel (PXc) includes a plurality of transistors (T1, T2, T3), a storage capacitor (Cst), and light emitting diodes (EDa, EDb, Edc) as light emitting devices. According to some embodiments, however, the pixels may include additional components or fewer components without departing from the spirit and scope of embodiments according to the present disclosure.

Here, one pixel (PXa, PXb, PXc) can be divided into light emitting diodes (EDa, EDb, EDc) and a pixel circuit unit, in FIG. 1, a plurality of transistors (T1, T2, T3) and a storage capacitor (Cst) may be included.

In addition, according to some embodiments, a capacitor (Cleda, Cledb, Cledc; hereinafter referred to as a light emitting unit capacitor) connected to both ends of the light emitting diode (EDa, EDb, EDc); hereinafter referred to as a light emitting capacitor) may be further included, and the light emitting capacitors (Cleda, Cledb, Cledc) may not be included in the pixel circuitry, and may be included in the light emitting diodes (EDa, EDb, EDc).

A plurality of transistors (T1, T2, T3) are formed of one driving transistor (T1; also known as first transistor) and two switching transistors T2, T3, and the two switching transistors are divided into input transistors (T2; also called second transistors) and initialization transistors (T3; also known as third transistors).

Each transistor (T1, T2, T3) includes a gate electrode, a first electrode, and a second electrode, respectively, and includes a semiconductor layer including a channel, and current flows or is blocked in the channel of the semiconductor layer according to the voltage of the gate electrode.

Here, the first electrode and the second electrode may be one of the two electrodes a source electrode and the other a drain electrode according to the voltage applied to each transistor (T1, T2, T3).

The gate electrode of the drive transistor (T1) is connected to one end (132a, 132b, 132c) of the maintenance capacitor (Cst), and is also connected to the second electrode (output side electrode) of the input transistor (T2).

In addition, the first electrode of the driving transistor (T1) is connected to the driving voltage line (172) transmitting the driving voltage (ELVDD), and the second electrode of the drive transistor (T1) is connected to an anode of the light emitting diode (EDa, EDb, EDc), the other ends (125a, 125b, 125c) of the maintenance capacitor (Cst), the first electrode of the initialization transistor (T3), the overlapping electrodes (BMLa, BMLb, BMLc), and the light emitting part capacitors Cleda, Cledb, Cledc.

The driving transistor (T1) receives data voltages (DVa, DVb, DVc) to the gate electrode according to the switching operation of the input transistor (T2), and can supply drive current to the light emitting diodes (EDa, EDb, EDc) according to the voltage of the gate electrode.

At this time, the maintenance capacitor (Cst) stores and maintains the voltage of the gate electrode of the driving transistor (T1).

Meanwhile, the overlapping electrodes (BMLa, BMLb, BMLc) may overlap with channels among the semiconductor layers included in the driving transistor (T1) to complement the characteristics of the channels of the driving transistor (T1).

The gate electrode of the input transistor (T2) is connected to the first scan signal line (151) transmitting the first scan signal (SC).

The first electrode of the input transistor (T2) is connected to the data lines (171a, 171b, 171c) for transmitting data voltages (DVa, DVb, DVc), and the second electrode of the input transistor (T2) is connected to one end of the maintenance capacitor (Cst) (132a, 132b, 132c), and the gate electrode of the driving transistor (T1).

The plurality of data lines (171a, 171b, 171c) transmit different data voltages (DVa, DVb, DVc), respectively, and the input transistors (T2) of each pixel (PXa, PXb, PXc) are connected to different data lines (171a, 171b, 171c).

The gate electrode of the input transistor (T2) of each pixel (PXa, PXb, PXc) may be connected to the same first scan signal line (151) to receive a first scan signal (SC) of the same timing.

Even if the input transistor (T2) of each pixel (PXa, PXb, PXc) is turned on at the same time by the first scan signal SC of the same timing, different data lines (171a, 171b, 171c), different data voltages (DVa, DVb, DVc) are transmitted to the gate electrode of the drive transistor (T1) of each pixel (PXa, PXb, PXc), and to one end (132a, 132b, 132c) of the maintenance capacitor (Cst).

The embodiments of FIG. 1 illustrate embodiments in which the gate electrode of the initialization transistor (T3) receives a scan signal different from the gate electrode of the input transistor (T2).

The gate electrode of the initialization transistor (T3) is connected to the second scan signal line (151-1) transmitting the second scan signal (SS).

The first electrode of the initialization transistor (T3) includes the other ends (125a, 125b, 125c) of the maintenance capacitor (Cst), the second electrode of the drive transistor (T1), the anode of the light emitting diode (EDa, EDb, EDc), the overlapping electrode (BMLa, BMLb, BMLc), and the light emitting part capacitor (Cleda, Cledb, Cledc), and the second electrode of the initialization transistor (T3) is connected to the initialization voltage line (173) that transmits the initialization voltage (VINT).

The initialization transistor (T3) is turned on according to the second scan signal SS to transmit the initialization voltage (VINT) to the anode of the light emitting diode (EDa, EDb, EDc), the end of the light emitting capacitor (Cleda, Cledb, Cledc), the overlapping electrode (BMLa, BMLb, BMLc), and the other ends (125a, 125b, 125c) of the maintenance capacitor (Cst) to initialize the voltage of the anode of the light emitting diode (EDa, EDb, EDc).

The initialization voltage line (173) may perform an operation to sense the voltage of the anode of the light emitting diode (EDa, EDb, EDc) before applying the initialization voltage (VINT), and may serve as a sensing wiring (SL).

Through the sensing operation, it may be possible to check whether the voltage of the anode is maintained at the target voltage.

The initialization operation that transmits the sensing operation and the initialization voltage (VINT) may be separated in time, and the initialization operation may be performed after the sensing operation is performed.

In the embodiments of FIG. 1, the turn on section of the initialization transistor (T3) and the input transistor (T2) may be distinguished, so that the input transistor (T2) performs a write in operation and the initialization transistor (T3) The initialization operation (and/or sensing operation) may be performed at different timings.

One end (132a, 132b, 132c) of the holding capacitor (Cst) is connected to the gate electrode of the drive transistor (T1) and the second electrode of the input transistor (T2), and the other ends (125a, 125b, 125c) are the first electrode of the initialization transistor (T3), the second electrode of the drive transistor (T1), the overlapping electrode (BMLa, BMLb, BMLc), the anode of the light emitting diode (EDa, EDb, EDc), and the light emitting part capacitor (Cleda, Cledb, Cledc).

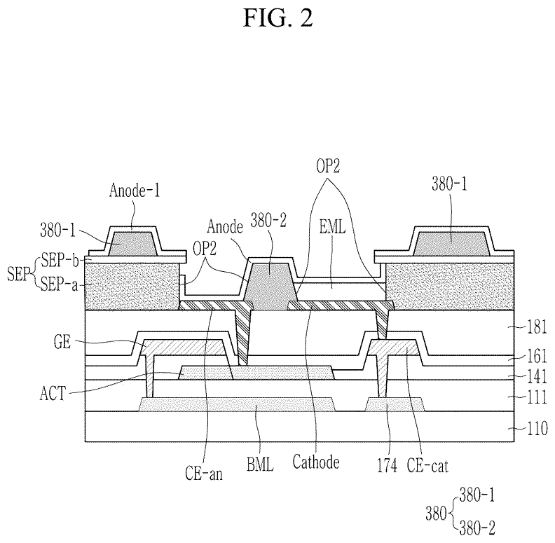

According to some embodiments, one end (132a, 132b, 132c) of the holding capacitor (Cst) may be positioned in the same layer as the overlapping electrode (see BML in FIG. 2).

Meanwhile, the other ends (125a, 125b, 125c) of the maintenance capacitor (Cst) may be positioned in a portion of the semiconductor layer (ACT of FIG. 2) of the drive transistor (T1) (a portion carved through a plasma treatment or doping process).

Here, a buffer layer (see 111 in FIG. 2) positioned between the semiconductor layer (ACT) and the overlapping electrode (BML) may serve as a dielectric layer of the maintenance capacitor (Cst).

The positions of one end (132a, 132b, 132c) and the other end (125a, 125b, 125c) of the maintenance capacitor (Cst) may be variously modified according to some embodiments.

The cathode of the light emitting diodes (EDa, EDb, and EDc) receives the drive low voltage (ELVSS) through the drive low voltage line (174), and the light emitting diodes (EDa, EDb, EDc) emits light according to the output current of the driving transistor (T1) to indicate the gradation.

In addition, a light emitting capacitor (Cleda, Cledb, Cledc) is formed at both ends of the light emitting diode (EDa, EDb, EDc) so that the cross-end voltage of the light emitting diode (EDa, EDb, EDc) can be kept constant, so that the light emitting diode (EDa, EDb, EDc) can display a certain luminance.

Hereinafter, a brief description will be taken into the operation of a pixel having a circuit as shown in FIG. 1.

In FIG. 1, each transistor (T1, T2, T3) is illustrated as an N-type transistor, and has a feature that is turned on when a high-level voltage is applied to the gate electrode.

However, according to some embodiments, each transistor (T1, T2, T3) may be a P-type transistor.

As the luminous section ends, a frame begins.

Thereafter, a high-level second scan signal (SS) is supplied to turn on the initialization transistor (T3).

When the initialization transistor (T3) is turned on, an initialization operation and/or a sensing operation may be performed.

Focusing on embodiments in which both initialization operation and detection operation are performed, it is as follows.

A sensing operation may be performed before the initialization operation is performed.

That is, as the initialization transistor (T3) is turned on, the initialization voltage line (173) plays the role of the sensing wiring (SL) to sense the voltage of the anode of the light emitting diode (EDa, EDb, EDc).

Through the sensing operation, it may be possible to check whether the voltage of the anode is maintained at the target voltage.

Thereafter, an initialization operation may be performed, and the other ends (125a, 125b, 125c) of the maintenance capacitor (Cst), the second electrode of the driving transistor (T1), the overlapping electrodes (BMLa, BMLb, BMLc), and the anode of the light emitting diode (EDa, EDb, EDc) are changed to the initialization voltage (VINT) transmitted from the initialization voltage line (173).

As described above, the initialization operation that transmits the sensing operation and the initialization voltage (VINT) is separated in time to reduce the area occupied by the pixel while using a minimum transistor.

As a result, the resolution of the display panel can be relatively improved.

In conjunction with the initialization operation or at a separate timing, the first scan signal (SC) is also applied while changing to a high-level, the input transistor (T2) is turned on, and a write operation is performed.

That is, the data voltages (DVa, DVb, DVc) from the data lines (171a, 171b, 171c) through the turn on input transistor (T2) are input and stored at one end (132a, 132b, 132c) of the gate electrode and the maintenance capacitor (Cst) of the drive transistor (T1).

By the initialization operation and the write operation, data voltages (DVa, DVb, DVc) and initialization voltages (VINT) are applied to both ends of the maintenance capacitor (Cst), respectively.

When the initialization transistor (T3) is turned on, even if the output current is generated in the driving transistor (T1), it can be output to the outside through the initialization transistor (T3) and the initialization voltage line (173), so that the light emitting diodes (EDa, EDb, EDc) may not be input.

In addition, according to some embodiments, the driving voltage (ELVDD) may be applied to a low-level voltage during the entry period in which the high-level first scan signal (SC) is supplied, or the drive low voltage (ELVSS) may be applied to a high-level voltage to prevent current from flowing to the light emitting diodes (EDa, EDb, EDc).

Then, when the first scan signal (SC) is changed to a low-level, the high-level driving voltage (ELVDD) applied to the driving transistor (T1) and the gate voltage of the driving transistor (T1) stored in the storage capacitor (Cst) are as a result, the driving transistor (T1) generates and outputs an output current.

The output current of the driving transistor (T1) is input to the light emitting diodes (EDa, EDb, EDc), and the light emitting diodes (EDa, EDb, EDc) emit light.

Unlike the embodiments of FIG. 1, according to some embodiments, the gate electrode of the initialization transistor (T3) may receive the same scan signal as the gate electrode of the input transistor (T2).

Hereinafter, the schematic cross-sectional structure of the pixel circuit part among the pixels (PXa, PXb, and PXc) having the circuit structure as shown in FIG. 1 will be described in detail through FIG. 2.

FIG. 2 is a cross-sectional view of a light emitting display device according to some embodiments.

The layer corresponding to the cathode, the separator (SEP), the pixel defining layer (380), the light emitting layer (EML), and the anode in the cross-sectional diagram of FIG. 2 is also called the light emitting device layer, and the lower part of the light emitting device layer, that is, the planarization layer (181) positioned at the bottom of the cathode, and the conductive layer constituting a transistor, a semiconductor layer, and an insulating layer.

The pixel defining layer (380) positioned in the light emitting device layer may be positioned on the separator (SEP) or may be positioned in a region where the separator (SEP) is not formed.

The region in which the pixel defining layer (380) and the separator (SEP) are not formed is referred to as the opening (OP1, OP2) below.

The light emitting device may correspond to a light emitting layer (EML) positioned in the first opening (OP1) of the region in which the pixel defining layer (380) and the separator (SEP) are not formed, and the first opening (OP1) is also referred to as the light emitting region.

In FIG. 2, one light emitting layer (EML) positioned in one light emitting region, that is, the first opening (OP1), and an anode positioned on top of the light emitting layer (EML) a path in which the current of the transistor included in the pixel driving part (PCa, PCb, PCc) positioned in the driving element layer is transmitted through the pixel defining layer (380) and the second opening (OP2) of the separator (SEP) is also shown.

In FIG. 2, the structure of the driving device layer is briefly shown, and only one transistor is briefly shown, and the structure of the drive device layer from the substrate (110) to the planarization layer (181) is briefly described below.

The substrate (110) may include a material that has rigid characteristics such as glass and does not bend, or may include a flexible material that can be wheeled, such as plastic or polyimide.

In the case of a flexible substrate, the two-layer structure of the barrier layer formed by the polyimid and the inorganic insulating material thereon may have a repeatedly formed structure.

An overlapping electrode (BML) including a metal is positioned on the substrate (110), and the overlapping electrode (BML) may overlap on a plane with one of the channels of the transistors positioned in the pixel driving part (PCa, PCb, PCc) included in the pixel.

In the embodiments of FIG. 2, a driving low voltage line (174) is positioned in which a second voltage (ELVSS) is applied to the same layer as the overlapping electrode (BML).

According to some embodiments, the overlapping electrode (BML) may be omitted, wherein the drive low voltage line (174) may be positioned in another conductive layer.

The substrate (110), the overlapping electrode (BML), and the drive low voltage line (174) are covered by the buffer layer (111).

The buffer layer (111) serves to block the infiltration of impure elements into the semiconductor layer (ACT), and may be an inorganic insulating layer including silicon oxide (SiOx) or silicon nitride (SiNx), silicon oxynitride (SiONx), and the like.

Above the buffer layer (111) is a semiconductor layer (ACT) positioned of a silicon semiconductor (e.g., polycrystalline semiconductor (P-Si)) or an oxide semiconductor.

The semiconductor layer (ACT) is a semiconductor layer positioned in a pixel driving part (PCa, PCb, and PCc) included in the pixel, and may include a channel of the transistor including a driving transistor and a first region and a second region positioned on both sides thereof.

Here, the channel of the transistor may be a part of the semiconductor layer (ACT) that overlaps the gate electrode (GE), and the first region and the second region are portions of the semiconductor layer (ACT) that do not overlap with the gate electrode (GE).

That is, the first region and the second region positioned on both sides of the channel of the semiconductor layer (ACT) are not covered by the gate electrode GE and have conductive layer characteristics by plasma treatment or doping.

On top of the semiconductor layer (ACT), the gate insulating layer (141) may be positioned.

The gate insulating layer (141) may be an inorganic insulating layer including silicon oxide (SiOx) or silicon nitride (SiNx), silicon oxynitride (SiONx), and the like.

A first gate conductive layer including a gate electrode (GE) of a transistor positioned in the pixel driving part (PCa, PCb, PCc) may be positioned on the gate insulating layer (141).

The first gate conductive layer may form a scan line in addition to the gate electrode (GE) of the transistor positioned in the pixel driving part (PCa, PCb, PCc).

Meanwhile, the first gate conductive layer may include one electrode of one capacitor positioned in the pixel driving part (PCa, PCb, PCc).

In addition, FIG. 2 includes an auxiliary electrode (CE-cat) connecting the drive low voltage line (174) and the cathode, and the auxiliary electrode (CE-cat) may be formed as a first gate conductive layer.

Referring to FIG. 2, the gate electrode (GE) and the auxiliary electrode (CE-cat) of the transistor may be connected to the overlapping electrode (BML) and the drive low voltage line (174) through an opening positioned in the gate insulating layer (141) and the buffer layer (111), respectively.

The first gate conductive layer may include a metal or metal alloy such as aluminum (AI), copper (Cu), molybdenum (Mo), titanium (Ti), and may be included of a single layer or multiple layers.

After forming the first gate conductive layer, a plasma treatment or a doping process may be performed to make an exposed region of the first semiconductor layer a conductor.

That is, the semiconductor layer (ACT) covered by the gate electrode (GE) is not conductive, and a portion of the semiconductor layer (ACT) not covered by the gate electrode (GE) may have the same characteristics as the conductive layer.

An interlayer insulating layer (161) may be positioned on the first gate conductive layer and the gate insulating layer (141).

The first interlayer insulating layer (161) may include an inorganic insulating layer including silicon oxide (SiOx) or silicon nitride (SiNx), silicon oxynitride (SiONx), and the like, and according to some embodiments, an inorganic insulating material may be thickened.

In addition, according to some embodiments, the interlayer insulating layer (161) may be formed as an organic insulating layer and may include one or more materials selected from the group consisting of polyimide, polyamide, acrylic resin, benzocyclobutene, and phenolic resin.

A planarization layer (181) is positioned on the interlayer insulating layer (161).

The planarization layer (181) and the interlayer insulating layer (161) expose the semiconductor layer (ACT) and the auxiliary electrode (CE-cat), respectively, and are on a plane with a portion of each of the semiconductor layer (ACT) and the auxiliary electrode (CE-cat) may contain overlapping openings.

The planarization layer (181) may be formed of an organic insulating layer and may include one or more materials selected from the group consisting of polyimide, polyamide, acrylic resin, benzocyclobutene, and phenol resin.

A data conductive layer including a connection electrode may be positioned between the interlayer insulating layer (161) and the planarization layer (181).

The structure of the driving device layer has been described above, and the structure of the light emitting device layer will be described in more detail below.

A first electrode layer including a cathode and an anode connection electrode (CE-an) is formed on the planarization layer (181).

The anode connection electrode (CE-an) is positioned within a region where no cathode is formed and is electrically separated from the cathode.

A portion of the cathode may overlap with the light emitting layer (EML) positioned within the pixel defining layer (380) and the first opening (OP1) of the separator (SEP), overlapping with the light emitting region, and may constitute a light emitting device.

The anode connection electrode (CE-an) is electrically connected to the anode in a subsequent process.

Here, the light emitting layer (EML) may include a color conversion material such as a quantum dot.

The first electrode layer may include a single layer including a transparent conductive oxide layer or a metal material, or multiple layers including the same.

The transparent conductive oxide layer may include indium tin oxide (ITO), poly-ITO, indium zinc oxide (IZO), indium gallium zinc oxide (IGZO), and indium tin zinc oxide (ITZO).

The metal material may include silver (Ag), molybdenum (Mo), copper (Cu), gold (Au), and aluminum (Al).

Above the planarization layer (181) has a double layer structure, and a separator (SEP) including a protruding tip structure is positioned on the upper layer, and at least a portion of the separator (SEP) may overlap a portion of the first electrode layer.

The separator (SEP) has a double layer structure including a lower layer (SEP-a; hereinafter referred to as a first layer) and an upper layer (SEP-b; hereinafter referred to as a second layer).

The lower layer (SEP-a) has a narrower width than the upper layer (SEP-b), and the upper layer (SEP-b) has a tip structure protruding from the lower layer (SEP-a).

Here, the width may be determined based on a vertical direction to the extending direction of the planar separator (SEP), and the width of the upper layer (SEP-b) is vertical to the extending direction with respect to two boundaries parallel to the extending direction, and the width of the lower layer (SEP-a) may be a spacing in a vertical direction to the extension direction with respect to two boundaries parallel to the extension direction.

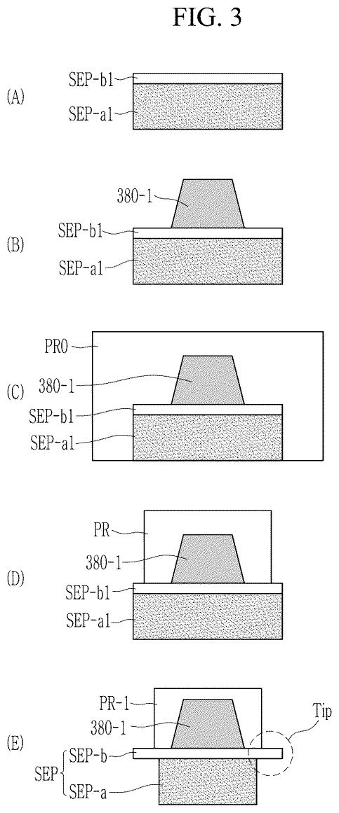

In addition, the boundary of the upper layer (SEP-b) in a plan view is positioned outside the boundary of the lower layer (SEP-a), and as shown in FIG. 3(E) in a cross-sectional view, a portion of the upper layer (SEP-b) is in contact with the lower layer (SEP-a), but the remaining portion of the upper layer (SEP-b), i.e., a portion close to the boundary, has a tip structure that does not come into contact with the lower layer (SEP-a) and protrudes.

The direction in which the tip structure protrudes may be parallel to or equivalent to the upper surface of the substrate (110), or may have a direction slightly inclined toward the substrate (110) due to gravity.

By the protruding tip structure of the upper layer (SEP-b), the layer (Anode) positioned on the upper part of the separator (SEP) can be broken without a separate etching process.

The separator (SEP) may not be positioned between the two openings (OP1) and (OP2) to allow the anode to be continuously formed.

Here, the lower layer (SEP-a) may be an organic insulating layer formed of an organic insulating material, and the upper layer (SEP-b) may be an inorganic insulating layer formed of an inorganic insulating material.

The organic insulating material included in the lower layer (SEP-a) may be at least one material selected from the group consisting of polyimide, polyamide, acrylic resin, benzocyclobutene, and phenol resin, and included in the upper layer (SEP-b). The inorganic insulating material to be used may be at least one of silicon oxide (SiOx), silicon nitride (SiNx), or silicon oxynitride (SiONx).

As a result, the lower layer (SEP-a) may be formed to be thicker than the upper layer (SEP-b).

A pixel defining layer (380) is formed on the planarization layer (181), the first electrode layer, and the separator (SEP).

The pixel defining layer (380) is a second pixel positioned between the first pixel defining layer (380-1) positioned above the separator SEP and the two openings (OP1, OP2) and does not overlap the separator (SEP), it can be divided into a second pixel defining layer (380-2).

The first opening OP1 positioned between the pixel defining layer (380) and the separator (SEP) may correspond to the light emitting device and/or the light emitting region.

The first opening (OP1) exposes a portion of the cathode, and the light emitting layer (EML) may be positioned in the first opening (OP1).

That is, the light emitting layer (EML) may be positioned within the first opening (OP1) divided by a separator (SEP) overlapping the second pixel defining layer (380-2) and the first pixel defining layer (380-1).

The second opening (OP2) is a portion to which the anode connection electrode (CE-an) and the anode are connected, and the pixel defining layer (380) and the separator (SEP) expose a portion of the anode connection electrode (CE-an) to be electrically connected to the anode formed subsequently.

That is, the second opening (OP2) is divided by a separator (SEP) overlapping the second pixel defining layer (380-2) and the first pixel defining layer (380-1), wherein the separator (SEP) dividing the second opening (OP2) may be a separator (SEP) and another separator (SEP) for compartmentalizing the first opening (OP1).

A second pixel defining layer (380-2) is formed between the two openings (OP1, OP2) and the separator (SEP) is not formed, so that the subsequent formed anode has a structure in which it is connected without separation.

In addition, a separator SEP is positioned on the outside of the two openings (OP1, OP2) and the anode subsequently formed may have a structure in which it is separated from the auxiliary electrode (Anode-1) on the outside.

Therefore, the auxiliary electrode (Anode-1) may be formed of the same material as the anode.

Above the exposed cathode, the exposed anode connection electrode (CE-an), the exposed separator (SEP), and the pixel defining layer (380) may be positioned a light emitting layer (EML), an anode, and an auxiliary electrode (Anode-1).

The light emitting layer (EML) is positioned in the first opening (OP1), and the light emitting layer (EML) may be formed by an inkjet method.

In addition, the light emitting layer (EML) may include a color conversion material such as quantum dots.

Meanwhile, a second functional layer may be positioned between the cathode and the light emitting layer (EML).

In addition, a first functional layer may be positioned on the light emitting layer (EML).

Here, the first functional layer may include a hole injection layer and/or a hole transport layer, and the second functional layer may include an electron delivery layer and/or an electron injection layer.

According to some embodiments, the first functional layer and the second functional layer may also be positioned on top of the pixel defining layer (380), and the two sides may be separated from each other based on the exposed separator (SEP).

Above the light emitting layer (EML), a second electrode layer including an anode is formed on top of the exposed separator (SE)P, the pixel defining layer (38)0, and the openings (OP1, OP2).

The anode is separated from the auxiliary electrode (Anode-1) by a protruding tip structure positioned in the exposed separator (SEP), and the anode is also formed in the second pixel defining layer (380-2) and the opening (OP1, OP2), some parts are also positioned above the light emitting layer (EML), and are also connected to the exposed anode connection electrode (CE-an).

Therefore, the anode is positioned on the anode connecting electrode (CE-an), the second pixel defining layer (380-2), and the light emitting layer (EML).

The auxiliary electrode (Anode-1) is positioned on the first pixel defining layer (380-1) and the separator (SEP) overlapping therewith, and according to some embodiments, the auxiliary electrode (Anode-1) is electrically connected to the cathode, a second voltage (ELVSS) may be applied.

The second electrode layer, including the anode and the auxiliary electrode (Anode-1), is a portion of the separator (SEP) that is not covered by the pixel defining layer (380) when stacked without a separate mask, that is, the tip structure of the upper layer (SEP-b) of the separator (SEP) is automatically separated.

Therefore, by the tip structure of the upper layer (SEP-b) of the exposed separator (SEP), the second electrode layer formed on top of the separator (SEP) is separated into an anode and an auxiliary electrode (Anode-1) without a separate etching process.

Referring to FIG. 2, the portion serving as a second electrode in the semiconductor layer (ACT) of the transistor and the anode connection electrode (CE-an) are electrically connected through an opening positioned in the gate insulating layer (141), the interlayer insulating layer (161), and the planar layer (181), and the anode connection electrode (CE-an) is transmitted to the anode through the second opening (OP2).

The current transmitted to the anode passes through the light emitting layer (EML) to the cathode, and the light emitting layer (EML) emits light due to the current flowing through the light emitting layer (EML), and the light emitting device exhibits luminance.

According to some embodiments, the semiconductor layer (ACT) of the transistor and the anode may not include an anode connection electrode (CE-an) or may further include an additional connection electrode.

Because FIG. 2 is a cross-sectional structure according to some embodiments, numerous variations structures may also be possible.

In the structure of FIG. 2, there are features in the structure of the separator (SEP) and the pixel defining layer (380) included in the light emitting device layer, and hereinafter, a method of manufacturing a separator (SEP) and a pixel defining layer (380) will be described in detail through FIG. 3.

FIG. 3 is a schematic cross-section view the manufacturing order of a portion of a light emitting display device according to some embodiments.

In FIG. 3, only the separator (SEP) and the first pixel defining layer (380-1) are shown.

As shown in FIG. 3 (A), the material for the lower layer and the material for the upper layer constituting the separator (SEP) are sequentially stacked, and the primary etch is performed to create a primary structure of the separator (SEP) having a lower layer (SEP-a1) and an upper layer (SEP-b1) in the region where the separator (SEP) is positioned.

Here, the primary structure of the separator (SEP) may have the same width as the lower layer (SEP-a1) and the upper layer (SEP-b1), and the upper layer (SEP-b1) may have a structure in which no tip structure is formed.

As a result, the separator (SEP) of the primary structure may have a structure in which the layer formed on top cannot be separated.

The lower layer (SEP-a1) may be an organic insulating layer formed of an organic insulating material, and the upper layer (SEP-b1) may be an inorganic insulating layer formed of an inorganic insulating material.

The organic insulating material included in the lower layer (SEP-a1) may be at least one material selected from the group consisting of polyimide, polyamide, acrylic resin, benzocyclobutene and phenolic resin, and the inorganic insulating material included in the upper layer (SEP-b1) may be at least one material of silicon oxide (SiOx) or silicon nitride (SiNx), silicon oxynitride (SiONx).

Here, the upper layer (SEP-b1) is formed as an inorganic insulating layer, so that the pixel defining layer (380) formed of an organic insulating material positioned at the top is not deteriorate adherence with the lower layer (SEP-a1), which is another organic insulating layer.

That is, when organic matter and organic matter come into contact, the adherence may generally be deteriorated, but the upper layer (SEP-b1) can be formed between to ensure adhesion.

Thereafter, as shown in FIG. 3 (B), the first pixel defining layer (380-1) of the pixel defining layer (380) is formed on the upper layer (SEP-b1) of the separator (SEP) primary structure.

That is, after laminating the organic insulating material for the pixel defining layer (380), the mask is used to develop exposure to form the first pixel defining layer (380-1).

At this time, the second pixel defining layer (380-2) may be formed together in a region where the separator (SEP) is not positioned at the bottom.

Here, the first pixel defining layer (380-1) positioned on top of the upper layer

(SEP-b1) is formed at a narrower width than the upper layer (SEP-b1) so that even if a process error occurs, the upper layer (SEP-b1) and the lower layer (SEP-a1) may not be positioned on the side.

Thereafter, as shown in FIG. 3 (C), a photoresist (PRO) is formed over the entire region.

Thereafter, as shown in FIG. 3 (D), the photoresist (PRO) formed in the entire region is exposed using a mask and developed to form a photoresist pattern (PR).

The photoresist pattern (PR) surrounds the pixel defining layer (380) including the first pixel defining layer (380-1) by a thickness (e.g., a set or predetermined thickness) or more so that the pixel defining layer (380) is not etched in a subsequent process.

In addition, the photoresist pattern (PR) is formed to expose the sides of the lower layer (SEP-a1) and the upper layer (SEP-b1) included in the primary structure of the separator (SEP) without covering it.

Thereafter, as shown in FIG. 3 (E), dry etching is performed to etch the lower layer (SEP-a1) and the upper layer (SEP-b1) included in the primary structure of the separator (SEP) not covered with the photoresist pattern (PR) to complete the upper layer (SEP-b) having a tip structure and the lower layer SEP-a.

At this time, the dry etching may be anisotropic dry etching, and the lower layer (SEP-a1) formed of the organic insulating material through anisotropic dry etching is normally etched, and the upper layer (SEP-b1) formed of the inorganic insulating material is slightly etched or not etched.

As a result, the upper layer (SEP-b) protruding from the lower layer (SEP-a) is completed as shown in FIG. 3 (E), and the upper layer (SEP-b) has a protruding tip structure.

At this time, the photoresist pattern (PR) is also etched and changed to a narrowed photoresist pattern (PR-1).

The photoresist pattern (PR-1) may still cover the pixel defining layer (380) including the first pixel defining layer (380-1).

Thereafter, the photoresist pattern (PR-1) is removed using a stripper or the like to complete the pixel defining layer (380) including the completed separator (SEP) and the first pixel defining layer (380-1).

Because the pixel defining layer (380) including the first pixel defining layer (380-1) is protected by a photoresist pattern (PR) in a dry etching process for completing the separator (SEP), the surface of the pixel defining layer (380) can maintain hydrophobic.

For example, if the surface of the pixel defining layer (380) is hydrophobic, the solution provided by the inkjet may be held so that it does not go beyond the pixel defining layer (380).

As a result, there may not be a problem in forming a light emitting layer with the inkjet process in the subsequent process.

Here, the light emitting layer may include a color conversion material such as a quantum dot.

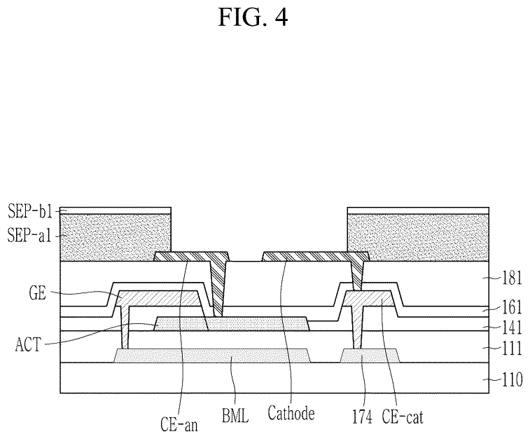

Hereinafter, a method of manufacturing an light emitting display device of FIG. 3 through the manufacturing method of FIG. 4 to FIG. 10 will be described in detail.

FIG. 4 to FIG. 10 are cross-sectional views shown according to the manufacturing order of the embodiments of FIG. 2.

First, in FIG. 4, after the driving element layer positioned below the planarization layer (181) is completed, a first electrode layer including a cathode and an anode connection electrode (CE-an) is completed on top of the planarization layer (181).

Thereafter, as shown in FIG. 4, the material for the lower layer and the material for the upper layer constituting the separator (SEP) are sequentially stacked, and the primary etch is performed to create a primary structure of the separator (SEP) having a lower layer (SEP-a1) and an upper layer (SEP-b1).

Here, the primary structure of the separator (SEP) may have the same width as the lower layer (SEP-a1) and the upper layer (SEP-b1), and the upper layer (SEP-b1) may have a structure in which no tip structure is formed.

In addition, the primary structure of the separator (SEP) has a structure covering a portion of the outer side of the cathode and the anode connection electrode (CE-an), and may not be positioned between the cathode and the anode connection electrode (CE-an).

In addition, the separator (SEP) of the primary structure may have a structure that does not have a tip structure and cannot separate the layer formed on top.

Here, the lower layer (SEP-a1) may be an organic insulating layer formed of an organic insulating material, and the upper layer (SEP-b1) may be an inorganic insulating layer formed of an inorganic insulating material.

The organic insulating material included in the lower layer (SEP-a1) may be at least one material selected from the group consisting of polyimide, polyamide, acrylic resin, benzocyclobutene and phenolic resin, and the inorganic insulating material included in the upper layer (SEP-b1) may be at least one of silicon oxide (SiOx), silicon nitride (SiNx), or silicon oxynitride (SiONx).

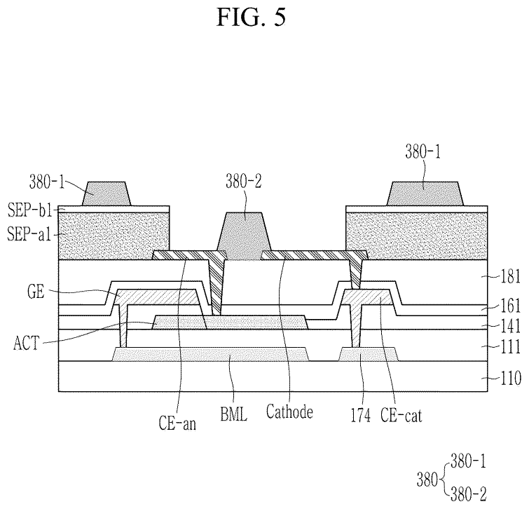

Thereafter, as shown in FIG. 5, a pixel defining layer (380) is formed on top of the separator (SEP) of the primary structure.

That is, after laminating the organic insulating material for the pixel defining layer (380), a mask is used to develop exposure to form the pixel defining layer (380).

At this time, the pixel defining layer (380) is not only the first pixel defining layer (380-1) in which the separator (SEP) is positioned at the bottom, but also the second pixel defining layer (380-2) positioned between the cathode and the anode connection electrode (CE-an), and the separator (SEP) is not positioned.

The first pixel defining layer (380-1) positioned on top of the separator (SEP) is formed in a narrower width than the upper layer (SEP-b1) of the separator (SEP) so that it is not positioned on the side of the upper layer (SEP-b1) and the lower layer (SEP-a1) even if a process error occurs.

The pixel defining layer (380) positioned on top of the separator (SEP) has improved adherence with the separator (SEP) by the upper layer (SEP-b1) formed of an inorganic insulating material.

That is, when organic matter and organic matter come into contact, the adherence may generally be reduced, but the upper layer (SEP-b1) can be formed between to ensure adherence.

On the other hand, the pixel defining layer (380) positioned between the cathode and the anode connection electrode (CE-an) in an region where the separator (SEP) is not positioned may have a structure covering one side of the cathode and the anode connection electrode (CE-an).

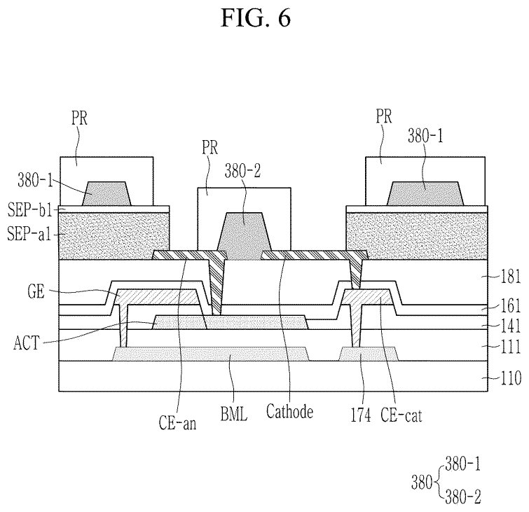

Thereafter, as shown in FIG. 6, a photoresist pattern (PR) is formed.

That is, after applying the photoresist to the entire region, the mask is used to exposure and develop to form a photoresist pattern (PR).

The photoresist pattern (PR) surrounds the pixel defining layer (380) by a certain thickness or more so that the pixel defining layer (380) is not etched in a subsequent process.

In addition, the photoresist pattern (PR) exposes the side of the separator (SEP) of the primary structure, so that the lower layer (SEP-a1) and the side of the upper layer (SEP-b1) of the separator (SEP) may not be covered.

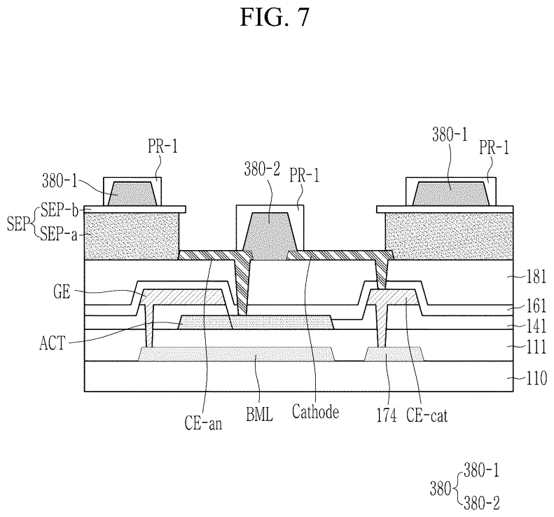

Thereafter, as shown in FIG. 7, dry etching is performed to etch the lower layer (SEP-a1) and the upper layer (SEP-b1) included in the separator (SEP) of the primary structure that is not covered with a photoresist pattern (PR) to complete the lower layer (SEP-a) and the upper layer (SEP-b) having a protruding tip structure.

At this time, the dry etching may be anisotropic dry etching, and the lower layer (SEP-a1) formed of the organic insulating material through anisotropic dry etching is normally etched, and the upper layer (SEP-b1) formed of the inorganic insulating material is slightly etched or not etched.

As a result, the upper layer (SEP-b) protruding from the lower layer (SEP-a) is completed, and the upper layer (SEP-b) has a protruding tip structure.

At this time, the photoresist pattern (PR) is also etched and changed to a narrowed photoresist pattern (PR-1).

The photoresist pattern (PR-1) may still cover the pixel defining layer (380).

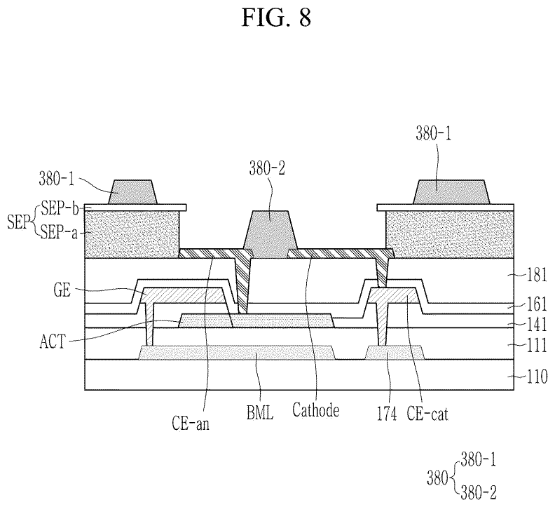

Thereafter, as shown in FIG. 8, the photoresist pattern (PR-1) is removed using a stripper or the like to complete the separator (SEP) and pixel defining layer (380).

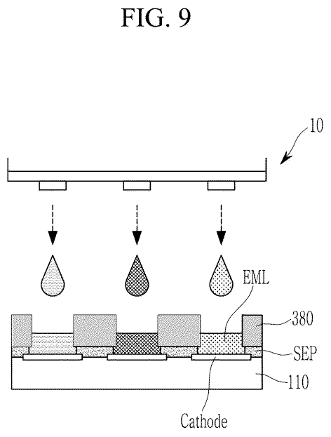

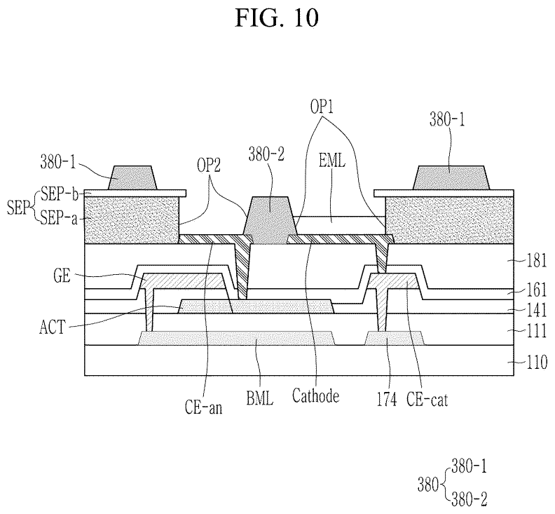

Thereafter, as shown in FIG. 9 and FIG. 10, an inkjet method forms a light emitting layer (EML).

Here, the light emitting layer may include a color conversion material such as a quantum dot.

In FIG. 9, a step of forming a light emitting layer (EML) in an inkjet manner through the inkjet facility (10) is shown, and in FIG. 10, a cross-sectional structure of a light emitting display device in which the light emitting layer (EML) is completed is shown.

Referring to FIG. 10, the light emitting layer (EML) is injected in an inkjet manner into the pixel defining layer (380) and the first opening (OP1) of the separator (SEP).

Referring to FIG. 10, the light emitting layer (EML) is positioned within the first opening (OP1) divided by a separator (SEP) overlapping the second pixel defining layer (380-2) and the first pixel defining layer (380-1).

Here, the first pixel defining layer (380-1) and the second pixel defining layer (380-2), which are the uppermost layers, are protected by photoresist in the process of forming the separator (SEP), so that the hydrophobic characteristics of the surface are maintained.

As a result, the material for the light emitting layer (EML) provided by the inkjet method does not go beyond the second pixel defining layer (380-2), and the light emitting layer (EML) can be accurately formed only within the first opening (OP1). In addition, the light emitting layer (EML) may include a color conversion

material such as a quantum dot, wherein a single inkjet process may provide a light emitting layer (EML) including a color conversion material, and according to some embodiments, a light emitting layer and a color conversion material may be formed through different inkjet processes, respectively.

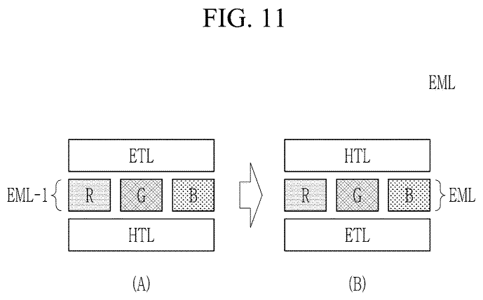

Meanwhile, functional layers (refer to HTL and ETL in FIG. 11) may be positioned above and below the light emitting layer (EML), and functional layers may be formed through a separate process.

Referring to FIG. 2, when the second electrode layer is stacked on top of the light emitting layer (EML), the pixel defining layer (380), the second opening (OP2), and the exposed separator (SEP), the anode and the auxiliary electrode (Anode-1) are separated by a protruding tip structure positioned in the separator (SEP).

The anode may or may not contact the bottom surface of the protruding tip structure of the upper layer (SEP-b) of the separator (SEP).

The anode may be connected to the anode connection electrode (CE-an) exposed in the second opening (OP2) and receive an output current of the transistor positioned at the bottom.

Here, the second opening (OP2) is divided by a separator (SEP) overlapping the second pixel defining layer (380-2) and the first pixel defining layer (380-1), wherein the separator (SEP) dividing the second opening (OP2) may be a separator (SEP) and a different separator (SEP) for partitioning the first opening (OP1).

In addition, the anode is also positioned above the light emitting layer (EML) to form a light emitting device together with the light emitting layer (EML) and the cathode.

The auxiliary electrode (Anode-1) is positioned on the first pixel defining layer (380-1) and the separator (SEP) overlapping therewith, and according to some embodiments, the auxiliary electrode (Anode-1) is electrically connected to the cathode a second voltage (ELVSS) may be applied.

Hereinafter, through FIG. 11, the stacking structure between the anode and the cathode of the light emitting device will be described in more detail.

FIG. 11 is a drawing illustrating the cross-sectional structure of the light emitting layer between the comparative example and some embodiments. In FIG. 11, the light emitting layer (EML, EML-1) and the functional layer

(ETL, HTL) positioned between the anode and the cathode of the light emitting device are schematically shown, FIG. 11 (A) is a structure of a comparative example, and FIG. 11 (B) is the structure of the embodiments of FIG. 2.

Comparing FIGS. (11 A) and (11 B), the upper and lower positions of the functional layers (ETL, HTL) are different.

Here, the first functional layer (HTL) may be a hole transport layer and may further include a hole injection layer.

Meanwhile, the second functional layer (ETL) may be an electron transfer layer and may additionally include an electron injection layer.

In the structure of the comparative example of FIG. 11(A), the anode is positioned at the bottom and the cathode is positioned at the top.

In contrast, in the structure of the embodiments of FIG. 11(B), the cathode is positioned at the lower part and the anode is positioned at the upper part.

Forming the light emitting layer(EML) through the inkjet process simplifies the process and lowers the manufacturing cost, but when forming the second functional layer (ETL) including the electron transport layer after forming the light emitting layer (EML), the electron transport layer damage may occur to the deterioration of the quality of the light emitting device.

Accordingly, as shown in FIG. 11(B), after the second functional layer (ETL) including an electron transport layer is first formed, the light emitting layer (EML) is formed by an inkjet process, and the first functional layer including a hole transport layer thereon is formed (HTL) can be formed to improve the quality of the light emitting device.

Based on this structure, the light emitting device may form an anode at the top and a cathode at the bottom as shown in FIG. 2.

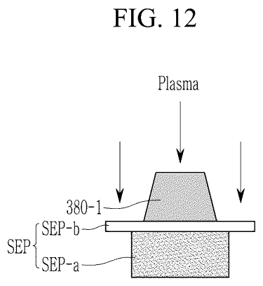

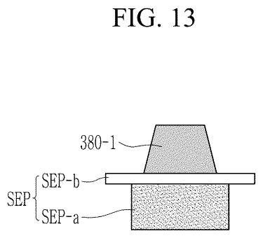

Hereinafter, through FIGS. 12 and 13, modified embodiments will be described.

First, modifications of embodiments with respect to FIG. 12 will be considered.

FIG. 12 is a cross-sectional view illustrating one step of a method of manufacturing a light emitting display device according to some embodiments.

In FIG. 12, a step after the step of FIG. 3 (E) is shown, and after the separator (SEP) is completed as shown in FIG. 3 (E), the photoresist pattern (PR-1) is removed using a stripper or the like.

As shown in FIG. 12, a plasma treatment including oxygen (O2) to the surface of the pixel defining layer (380) in which the photoresist pattern (PR-1) is removed and exposed is performed to improve the hydrophobic characteristics of the surface of the pixel defining layer (380).

As a result, the light emitting layer provided by the inkjet method does not go beyond the surface of the pixel defining layer (380) having hydrophobicity, so that the light emitting layer can be more easily formed at the desired position.

Meanwhile, hereinafter, modified embodiments with respect to FIG. 13 will be considered.

FIG. 13 is a cross-sectional view of a portion of a light emitting display device according to some embodiments.

According to some embodiments as illustrated in FIG. 13, unlike the preceding embodiments, the lower layer (SEP-a) of the separator (SEP) is also formed as an inorganic insulating layer formed of an inorganic insulating material.

The lower layer SEP-a may be formed of at least one material of silicon oxide (SiOx) or silicon nitride (SiNx) or silicon oxynitride (SiONx).

Both the lower layer (SEP-a) and the upper layer (SEP-b) of the separator (SEP) are formed as inorganic insulating layers, but in order to form a tip structure, two types of inorganic insulation layers having different dry etching characteristics (e.g., etch rate, etc.) It is necessary to form a layer of inorganic insulation, and the upper layer (SEP-b) may have a small value of dry etching rate compared to the lower layer (SEP-a).

According to some embodiments, the lower layer (SEP-a) and the upper layer (SEP-b) are etched together through anisotropic dry etching, but the upper layer (SEP-b) is relatively little etched and may have a tip structure.

The lower layer (SEP-a) of the separator (SEP) is formed as an inorganic insulating layer, but the layer (anode) positioned at the top by the upper layer (SEP-b) having a tip structure by thickly stacking the inorganic insulating layer can be formed so that it can be separated more easily.

According to some embodiments, not only the light emitting layer may be formed in an inkjet manner, but the anode may also have a structure that is separated without separate etching.

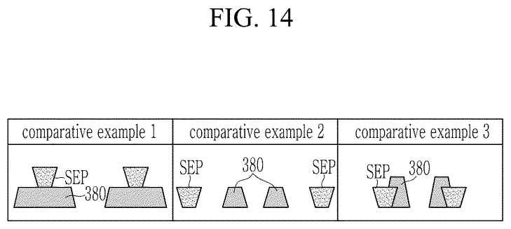

In addition, the light emitting display apparatus formed by the above-described embodiments may form a high-resolution light emitting display device by narrowing the gap between adjacent light emitting devices or the light emitting region, and in this regard, the separator (SEP) and the pixel defining layer (380) are formed in comparison with the comparative examples of FIG. 14.

FIG. 14 is a schematic drawing illustrating a cross-sectional structure of a plurality of comparative examples.

In FIG. 14, the structure of three comparative separators SEP and pixel defining layer (380) is shown.

In the comparative examples, they all have separators (SEPs) with inverted tapered sidewalls.

In comparative example 1, a separator (SEP) having an inverted tapered sidewall is formed on top of the pixel defining layer (380).

In comparative example 2, the pixel defining layer (380) and the separator (SEP) are positioned on the same layer, but the pixel defining layer (380) may be formed after forming the separator (SEP).

In addition, the pixel membrane (380) has a tapered sidewall, and the separator (SEP) has an inverted tapered sidewall.

In comparative example 3, a part of the separator (SEP) is a structure having a covering pixel defining layer (380), and only the inverted tapered side wall of the exposed separator (SEP) performs the role of the separator (SEP).

If the minimum line width in which the organic layer can be formed in the organic layer formation process is 10 μm, the minimum spacing between the organic layers is 5 μm, and the minimum overlap width in which the organic layers can overlap is 5 μm, the interval between the light emitting layers positioned between the adjacent pixel justice membranes (380) can be simulated.

In comparative example 1, a separator (SEP) is formed on top of the pixel defining layer (380), and even if the separator (SEP) is formed at a minimum line width of 10 μm, the pixel defining layer (380) must be formed to a larger width so that the separator SEP can be stably positioned on the pixel defining layer (380).

Therefore, the pixel defining layer (380) of comparative example 1 can be formed at 20 μm in consideration of the process error.

In the structure of comparative example 1, because the spacing between adjacent light emitting layers may correspond to the width of the pixel defining layer (380), a light emitting layer may be positioned every 20 μm, so that a numerically high-resolution light emitting display device can be formed.

However, in comparative example 1, in the process of etching the separator (SEP) after forming the pixel defining layer (380), the surface of the pixel defining layer (380) is removed from hydrophobicity, and it is difficult drawback to form by the inkjet method.

On the contrary, in comparative example 2 and comparative example 3, because the separator (SEP) is formed first, the hydrophobicity of the pixel defining layer (380) is maintained to form a light emitting layer in an inkjet manner.

However, in comparative example 2 and comparative example 3, the light emitting layer is positioned only between the adjacent pixel defining layers (380), and the space between the adjacent pixel defining layers (380) and the separator (SEP) and the space between the adjacent separators (SEP) are secured, it is necessary to form a relatively far distance between adjacent light emitting layers.

For example, in comparative example 2, the light emitting layer positioned between the pixel defining layer (380) may be spaced about 45 μm with other light emitting layers, and in example 3, the spacing between adjacent light emitting layers may be about 40 μm.

Therefore, it is difficult to form a relatively high-resolution light emitting display device.

On the contrary, referring to the embodiments of FIG. 2, because the pixel defining layer (380) and the separator (SEP) completely overlap, the gap between adjacent light emitting layers may be narrower than in comparative example 3.

As a result, according to some embodiments, while forming a light emitting layer by an inkjet process, the gap between adjacent light emitting layers can be reduced to form a high-resolution light emitting display device.

Although aspects of some embodiments have been described in detail above, the scope of rights of the present invention is not limited thereto, and various modifications and modifications of those skilled in the art using the basic concepts of the present invention defined in the following claims also fall within the scope of the present invention as defined in the appended claims, and their equivalents.

### DESCRIPTION OF SOME OF THE REFERENCE SYMBOLS

| | |
|---|---|
| SEP: separator | SEP-a, SEP-a1: lower/first layer |
| SEP-b, SEP-b1: upper/second layer | 380: pixel defining layer |
| 380-1: first pixel defining layer | |
| 380-2: second pixel defining layer | |
| OP1, OP2: opening | Anode: anode |
| Anode-1: auxiliary electrode | |
| CE-an: anode connection electrode | |
| CE-cat: auxiliary electrode | Cathode: cathode |
| EML: light emitting layer | ETL, HTL: functional layer |
| Tip: tip | PXa, PXb, PXc: pixel |
| T1, T2, T3: transistor | PCa, PCb, PCc: pixel driving part |
| Cst: storage capacitor | |
| EDa, EDb, EDc: light emitting diode (LED) | |
| 151: first scan signal line | 151-1: second scan signal line |
| 171a, 171b, 171c: data line | 172: driving voltage line |
| 173: initialization voltage line | 174: driving low voltage line |
| 110: substrate | 111: buffer layer |
| 141: gate insulating layer | 161: interlayer insulating layer |
| 181: planarization layer | 10: Inkjet equipment |
| ACT: semiconductor layer | GE: gate electrode |
| Cleda, Cledb, Cledc: light emitting capacitor | |
| BML, BMLa, BMLb, BMLc: overlapping electrode | |
| 125a, 125b, 125c: lower storage electrode | |
| 132a, 132b, 132c: second semiconductor | |
| PR, PR0, PR-1: photo resist pattern | |

What is claimed is:

1. A light emitting display device, comprising:
a substrate;
a driving element layer on the substrate and including a transistor and a planarization layer covering the transistor;
a cathode and an anode connection electrode on the planarization layer;
a separator on the planarization layer and including a first layer and a second layer, wherein the second layer protrudes from the first layer of the separator;
a pixel defining layer including a first pixel defining layer on the separator and a second pixel defining layer superimposed with a portion of the cathode and a portion of the anode connection electrode;
a light emitting layer on top of the cathode; and
an anode connecting electrode, the second pixel defining layer, and an anode above the light emitting layer.

2. The light emitting display device of claim 1, wherein:
the first layer of the separator is a light emitting display device formed narrower in width than the second layer.

3. The light emitting display device of claim 2, wherein:
the first layer of the separator is formed narrower in width than the second layer,
the first pixel defining layer has a width narrower than the second layer and the first layer of the separator overlapping the first pixel defining layer.

4. The light emitting display device of claim 3, wherein:
the light emitting layer is positioned in a first opening divided by the separator overlapping the second pixel defining layer and the first pixel defining layer.

5. The light emitting display device of claim 4, wherein:
the anode is connected to the anode connection electrode through a second opening divided by the separator overlapping the second pixel defining layer and the first pixel defining layer.

6. The light emitting display device of claim 5, wherein:
the second pixel defining layer is between the first opening and the second opening.

7. The light emitting display device of claim 1, further comprising:
an auxiliary electrode on the first pixel defining layer and the separator overlapping therewith, and formed of a same material as the anode.

8. The light emitting display device of claim 1, further comprising:
a first functional layer between the light emitting layer and the anode, and comprising a hole transport layer; and
a second functional layer between the light emitting layer and the cathode and including an electron transmission layer.

9. The light emitting display device of claim 1, wherein:
the second layer of the separator is an inorganic insulating layer, and the first layer is an organic insulating layer.

10. The light emitting display device of claim 1, wherein:
the second layer of the separator is an inorganic insulating layer, and the first layer is an inorganic insulating layer having an etching rate different from the second layer.

11. A method of manufacturing a light emitting display device, the method comprising:
forming a transistor on a substrate, a planarization layer covering the transistor, and a cathode and an anode connection electrode on the planarization layer;
forming a primary structure of a separator by sequentially stacking a material for a first layer and a material for a second layer of the separator;
forming a first pixel defining layer on the primary structure of the separator;
forming a photoresist pattern covering the first pixel defining layer and exposing a side of the primary structure of the separator; and
etching the primary structure of the separator exposed through dry etching to complete a second layer of the separator protruding from the first layer of the separator.

12. The method of manufacturing a light emitting display device of claim 11, wherein:
the second layer and the first layer included in the primary structure of the separator have a same width as each other.

13. The method of manufacturing a light emitting display device of claim 12, wherein:
in the step of forming a first pixel defining layer on the primary structure of the separator, the first pixel defining layer on top of the primary structure of the separator is the second layer included in the primary structure and formed in a width narrower than the first layer.

14. The method of manufacturing a light emitting display device of claim 11, wherein:
in forming the first pixel defining layer on the primary structure of the separator, a second pixel defining layer that does not overlap with the separator is also formed.

15. The method of manufacturing a light emitting display device of claim 14, wherein:
the second pixel defining layer overlaps a portion of the cathode and a portion of the anode connection electrode.

16. The method of manufacturing a light emitting display device of claim 15, further comprising:
in an inkjet manner in a first opening compartmentalized by the separator overlapping the second pixel defining layer and the first pixel defining layer.

17. The method of manufacturing a light emitting display device of claim 16, wherein:
the light emitting layer comprises a quantum dot.

18. The method of manufacturing a light emitting display device of claim 11, wherein:
the step of completing the second layer of the separator is performed through anisotropic dry etching.

19. The method of manufacturing a light emitting display device of claim 11, wherein:
the material for the second layer is an inorganic insulating material, and the material for the first layer is an organic insulating material.

20. The method of manufacturing a light emitting display device of claim 11, wherein:
the material for the second layer is an inorganic insulating material, and the material for the first layer is an inorganic insulating material having an etching rate different from the material for the second layer.
